(19) United States
(12) Patent Application Publication
(10) Pub. No.: US 2026/0246479 A1
(43) Pub. Date: Aug. 20, 2026

(54) CURRENT-MODE ANALOG-TO-DIGITAL CONVERTER SYSTEMS, DEVICES AND METHODS FOR MULTI-SENSING

(71) Applicant: Cypress Semiconductor Corporation, San Jose, CA (US)

(72) Inventors: Andriy MAHARYTA, Lviv (UA); Oleksandr Karpin, Lviv (UA); Paul Walsh, Cork (IE); Mark Healy, Cork (IE)

(73) Assignee: Cypress Semiconductor Corporation, San Jose, CA (US)

(21) Appl. No.: 19/289,896

(22) Filed: Aug. 4, 2025

Related U.S. Application Data
(63) Continuation of application No. 17/314,998, filed on May 7, 2021, now Pat. No. 12,381,569.

(51) Int. Cl. H03M 1/34; G01D 5/14; G01R 17/02

(52) U.S. Cl. CPC H03M 1/34; G01D 5/14; G01R 17/02

(57) ABSTRACT

A device can include analog circuits formed with a substrate, including a comparator, analog switches, and a balance current circuit. A sensor current and balance current can be applied at an input of the comparator. The sensor current, balance current or both can be modulated with a switch control signal. Digital circuits can include switch control logic that generates the switch control signal in response to an output of the comparator and a modulation clock signal. Digital signal processing circuits can generate a multi-bit digital value from a bit stream output by the comparator circuit. The multi-bit digital value can be an analog-to-digital conversion of the sensor current. Corresponding methods and systems are also disclosed.

### RELATED APPLICATIONS

This application is a Continuation Application of U.S. patent application Ser. No. 17/314,998, filed on May 7, 2021, now U.S. Pat. No. 12,381,569, which is incorporated by reference herein in their entirety.

### TECHNICAL FIELD

The present disclosure relates generally to analog-to-digital converters (ADCs), and more particularly to ADCs configurable to operate with a variety of different sensor types.

### BACKGROUND

Conventional analog-to-digital converters (ADCs) are used in a wide number of applications, including sensor systems. FIGS. 30A and 30B are schematic diagrams of conventional sensor systems 3001A and 3001B. Sensor systems 3001A/B can include a sensor resistance Rsa/Rsb, which can vary according to a sensor response, in series with a fixed resistance Rd. A reference voltage source Vref can result in the generation of a measured voltage Vxa/Vxb by voltage division across the resistances Rs/Rd. A voltage mode ADC circuit can convert the measured voltage Vxa/Vxb into a digital value (RAW DATA). Typically, the ADC can use the same reference voltage Vref in the conversion operation. In the case of FIG. 30A, a sensor resistance value Rsa can be given by the following:

$$Vxa = \frac{Rsa}{Rd + Rsa} \cdot Vref \\ Rsa = \frac{Vxa}{Vref - Vxa} \cdot Rd$$

In the case of FIG. 30B, a sensor resistance Rsb can be given by the following:

$$Vxb = \frac{Rd}{Rd + Rsb} \cdot Vref$$

$$Rsb = ( \frac{Vref}{Vxb} - 1 ) \cdot Rd$$

Accordingly, a sensed resistance Rsa/Rsb is non-linear with respect to the Vx value. As a result, a sensitivity of a system depends on the sensor resistance Rsa/Rsb.

A drawback to resistive divider approaches like those of FIGS. 30A and 30B can be the non-linearity between a sensed resistance and converted voltage value; the necessity of a reference voltage; limitations in dynamic range due to the resistance divider; and the waste of static current through the resistance divider.

FIGS. 31A to 31C show various examples of conventional photoelectric and pyroelectric sensing systems. FIG. 31A shows a photoelectric sensing system 3101A. A sensor, such as one based on a photodiode, can serve as a current source 3103 which generates a current (I) that can vary according to a sensor operation. An amplifier stage 3105 can generate a sense voltage (V) from the current (I). A sense voltage (V) can be filtered with a bandpass filter (BPF) to generate a filtered voltage VF. Filtered voltage VF can be applied to a rectifier to generate a rectified voltage V_{R}. Rectified voltage V_{R} can be applied to an ADC circuit to generate a conversion (i.e., digital) output (RAW DATA). The rectified voltage V_{R} can be applied to a low pass filter (LPF) and serve as a feedback voltage to amplifier stage 3105.

FIG. 31B shows a conventional passive infrared (PIR) sensor system 3101B. A PIR detector 3107 can generate a current (I) in response to IR radiation. A sensor system 3101B can include a sensor resistance Rs which can generate a sense voltage Vs in response to sensor current (I). A sense voltage Vs can be filtered with a BPF, and the resulting voltage amplified with a gain stage (Gain). A voltage ADC circuit can convert the amplified voltage into a digital value (Dout). System 3101B can be conceptualized as converting a light generated charge (Q) into a current (I) into a voltage (V) into a digital value (D).

FIG. 31C shows a conventional photodetector system 3101C. Light (RA) detected by a photodiode can generate a current (I). Current (I) can be input to an amplifier stage which can generate a voltage (V). Voltage (V) can be sampled/modulated (SW) before being converted into a digital output value Dout by ADC. System 3101C can be conceptualized as converting a current (I) into a voltage (V) into a digital value (D).

Conventional sensor systems, like those described herein, can include an intermediate stage to convert a sensor current into a sensed voltage, such as a transimpedance amplifier (TIA), integrator, or passive element structure. The sensed voltage is then be converted into a digital value by a voltage ADC (V-ADC).

A drawback to conventional approaches like those of FIGS. 31A to 31C can be complexity and expense.

It would be desirable to arrive at an ADC system that does not suffer from drawbacks of conventional approaches.

### BRIEF DESCRIPTION OF THE DRAWINGS

FIG. 1 is a block diagram of a sensor system according to an embodiment, FIGS. 2A to 2D are block diagrams of sensor systems according to other embodiments.

FIG. 3 is a block schematic diagram of a current analog-to-digital converter (C-ADC) circuit according to an embodiment.

FIGS. 4A to 4D are schematic diagram of current sensing systems according to embodiments.

FIGS. 5A and 5B are schematic diagram of resistance sensing ADC systems according to embodiments.

FIGS. 6A and 6B are schematic diagram of resistance sensing ADC systems having modulated balance current sources according to embodiments.

FIGS. 7A and 7B are schematic diagram of resistance sensing ADC systems having modulated sensor currents according to embodiments.

FIG. 8 is a graph comparing ADC conversion results between embodiments with and without current modulation.

FIGS. 9A and 9B are schematic diagrams of sensor ADC systems with a sensor current source and a switched capacitor balance current generator according to embodiments.

FIGS. 10A and 10B are schematic diagrams of sensor ADC systems with a sensor resistance and a switched capacitor balance current generator according to embodiments.

FIG. 11 is a timing diagram showing ADC current sense operations according to embodiments.

FIGS. 12A and 12B are schematic diagrams of sensor ADC systems with a modulated sensor current source and switched capacitor balance current generator according to embodiments.

FIG. 13 is a schematic diagram of a photosensing ADC system according to an embodiment.

FIG. 14 is a schematic diagram of a photodiode equivalent circuit.

FIG. 15 is a timing diagram showing operations for an embodiment like that of FIG. 13.

FIGS. 16A and 16B are diagrams showing a proximity sensor that can be included in embodiments.

FIG. 17A is a schematic diagram of a proximity detection ADC system according to an embodiment. FIG. 17B is a block schematic diagram of an embodiment with active integrator circuits. FIG. 17C is a block schematic diagram of an embodiment having a higher order of modulation.

FIG. 18 is a timing diagram showing operations for an embodiment like that of FIG. 17A.

FIGS. 19A to 19D are schematic diagrams showing differential sensing operations for an embodiment like that of FIG. 17A.

FIG. 20 is a schematic diagram of a light intensity sensing ADC system according to an embodiment.

FIGS. 21A and 21B are schematic diagrams showing differential sensing operations for an embodiment like that of FIG. 20.

FIG. 22 is a schematic diagram of a passive infrared (PIR) proximity detection ADC system according to an embodiment.

FIG. 23 is a graph showing ADC conversion results according to an embodiment.

FIG. 24 is a graph showing results of a system like that of FIG. 22.

FIG. 25 is a block diagram of a multi-sense system according to an embodiment.

FIG. 26 is a block diagram showing various systems and applications according to embodiments.

FIG. 27 is a flow diagram of a method according to an embodiment.

FIG. 28 is a flow diagram of a method according to another embodiment.

FIG. 29 is a flow diagram of a method according to a further embodiment.

FIGS. 30A and 30B are schematic diagrams of conventional ADC systems.

FIG. 31A to 31C are diagrams showing conventional sensor systems with voltage ADCs.

### DETAILED DESCRIPTION

Embodiments can include a current-mode analog-to-digital converter (C-ADC) that can serve as a common architecture for a wide range of different sensing methods and sensor types. According to embodiments, a C-ADC can execute conversions, such resistance-to-code inversions, with an architecture that is relatively insensitive to current source, power supply and reference voltage variations, unlike conventional approaches. Any variety of current based sensing types can be accommodated, including but not limited to: capacitance sensing, inductance sensing, and resistance sensing. Sensing can be single ended or differential.

According to embodiments, a C-ADC can include an analog comparator that generates an output bit stream based on an input that can vary according to a sensor current. When the analog comparator input exceeds a threshold, the analog comparator output can transition varying the bit stream. The effect of the sensor current at an input of the comparator can be balanced by a balance current.

In some embodiments, a sensor current can be modulated in response to an analog comparator bit stream output.

In some embodiments, a balance current can be modulated in response to an analog comparator bit stream output. In some embodiments, a balance current can be generated with a switched capacitor circuit.

In the various embodiments described herein, like items are referred to by the same reference characters, but with the leading digit(s) corresponding to the figure number.

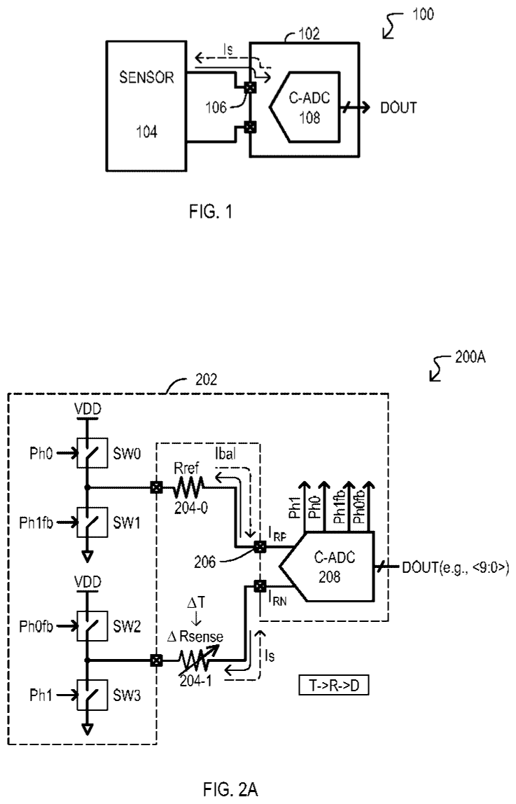

FIG. 1 is a block diagram of a system 100 according to an embodiment. A system 100 can include an ADC section 102 that can receive a sensor current (Is) from a sensor device 104. A sensor current (Is) can be received as an input through a physical connection 106. A direction of a sensor current (Is) can vary according to application and the type of sensor device 104. In some embodiments, ADC section 102 includes a C-ADC circuit 108 that does not include any intermediate circuit for a current-to-voltage conversion, and thus can directly receive a sensor current (Is). In this way, a C-ADC system 100 can be less complex and/or costly than conventional approaches.

FIG. 2A to 2D are diagrams showing various sensing systems according to embodiments. According to embodiments, a same C-ADC system can be employed in multiple different sensor applications. FIG. 2A shows a temperature sensing system 200A according to an embodiment. A system 200A can include a sensor resistance Rsense 204-1, a reference resistance Rref 204-0, and an ADC section 202. A sensor resistance 204-1 can vary in resistance in response to changes in temperature (T). A reference resistance 204-0 can be selected based on an expected range of sensor resistance 204-1.

ADC section 202 can include C-ADC circuit 208 and switches SW0 to SW3. C-ADC circuit 208 can generate switch control signals Ph0, Ph1, Ph0fb and Ph1fb. Switch control signal Ph0 can turn switch SW0 on when in an active state. Switch control signal Ph1 can turn switch SW3 on when at an active level (e.g., high). Switch control signals Ph0fb and Ph1fb can turn on switches SW2 and SW1, respectively, when in an active state. Control signals Ph0/Ph1 have active levels that do not overlap in time. Further, switch control signals Ph0/Ph1 will vary (e.g., frequency) according to an expected sensor current (Is). Switch control signals Ph0fb/Ph1fb can be modulated according to a feedback loop within C-ADC circuit 208 as Is increases and/or decreases. According to embodiments, as switches SW2/SW3 operate to generate a sensor current (Is), switches SW0/SW1 can generate a balance current (Ibal) that counteracts the effect of Is at the input of C-ADC circuit 208. It is understood that the various switch control signals Ph0/Ph0fb/Ph1/Ph1fb can vary according to the current flow direction of Is and Ibal.

In response to currents sensed at a first input (IRP) and a second input (I_{RN}), C-ADC circuit 208 can generate a digital output value DOUT. DOUT can include any suitable number of bits, and in the embodiment shown, includes 10-bits. In some embodiments, ADC section 202 can form part of a same integrated circuit device having external connections (one shown as 206) to reference and sensor resistances 204-0/1. A system 200A can be conceptualized as converting a temperature (T) into a resistance (R) into a digital value (D).

FIG. 2B shows a passive infrared (PIR) sensing system 200B according to an embodiment. A system 200B can include a PIR sensor 204B and an ADC section 202B. In response to incident IR radiation, a PIR sensor 204B can generate a sensor current (Is). Sensor current (Is) can be received as an input current IRP via an external connection 206, and provided to a C-ADC circuit 208. According to embodiments, unlike a conventional PIR sensing system, a sensor current (Is) does not flow through a resistor to be converted into a sense voltage. In some embodiments, a sensor current (Is) can be directly received by C-ADC circuit 208 for conversion into a digital output value DOUT. DOUT can be any suitable multi-bit value, and in the embodiment shown, can include 10-bits. A system 200B can be conceptualized as converting a light-induced charge (Q) into a current (I) into a digital value (D).

FIG. 2C shows a self-capacitance sensing system 200C according to an embodiment. A system 200C can include a sense capacitance 204-1C (or 204-1C′) and ADC section 202C. A sense capacitance 204-1C can vary in response to external events (e.g., proximity of an object). While a sense capacitance 204-1C can take the form of a capacitor with a dielectric, embodiments can include any suitable structure that provides a variation in capacitance, such as a switched capacitor resistor (SCR), as but one of many possible examples.

ADC section 202C can include C-ADC circuit 208 and switches SW0 and SW1. C-ADC circuit 208 can generate switch control signals Ph0 and Ph1 for controlling SW0 and SW1, respectively. Control signals Ph0/Ph1 can have active levels that do not overlap in time, and can vary (e.g., frequency, duty cycle) according to an expected sensor current (Is). In response to a current sensed at an input (IRP), C-ADC circuit 208 can generate a digital output value DOUT. In some embodiments, ADC section 202 can form part of a same integrated circuit device having external connections (one shown as 206). A system 200C can be conceptualized as converting a capacitance (C) into a current (I) into a digital value (D).

FIG. 2D shows a photoelectric sensing system 200D according to an embodiment. A system 200D can include a photoelectric device 204-1D and an ADC section 202D. In response to incident light of predetermined wavelengths, photoelectric device 204-1D can function as a current source and generate a sensor current (Is). A photoelectric device 204-1D can be any suitable device that generates current in response to light, including but not limited to a photodiode or phototransistor. Sensor current (Is) can be received as an input current IRP via an external connection 206. According to embodiments, unlike a conventional photoelectric sensing system, a sensor current (Is) is not applied to a voltage conversion stage (e.g., TIA). In some embodiments, a sensor current (Is) can be directly received by C-ADC circuit 208 for conversion into a digital output value DOUT. A system 200D can be conceptualized as converting a current (I), essentially directly, into a digital value (D).

Referring still to FIGS. 2A to 2D, in some embodiments an ADC section (202, 202B, 202C, 202D) can be the same current sensing architecture, adaptable to the various different systems. This is in contrast to conventional approaches that can include circuits designed for one application. In some embodiments, an ADC section (202, 202B, 202C, 202D) can include configurable circuits for enabling different analog signal paths between circuit sections and/or enabling different digital signal processing and signal timing to meet the needs of a desired application.

While FIGS. 2A to 2D show particular applications, embodiments can include various other sensor types that generate a current output signal or rely on resistance sensing. Embodiments with sensors that generate current output can include a pyroelectric sensor or an electret type sensor (e.g., electret microphone), as but two examples. Such current sensing embodiments can combine amplification and quantization in one conversion operation. This is in contrast to conventional approaches which include separate pre-amplifier prior to quantization. Embodiments with resistance sensing can also include temperature sensors (both negative and positive dependence), resistive force sensors, resistive pressure sensors, resistive touch sensors (e.g., touchpad, button). Such resistance sensing embodiments can include a direct resistance-to-code conversion with a phased switching architecture. This is in contrast to conventional approaches which convert a resistance to a sense voltage, and then apply the sense voltage to a voltage ADC.

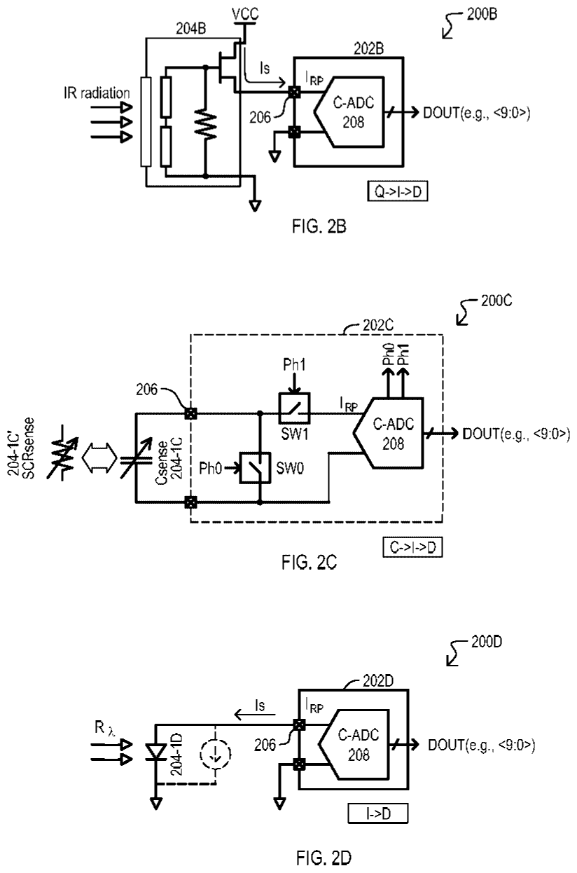

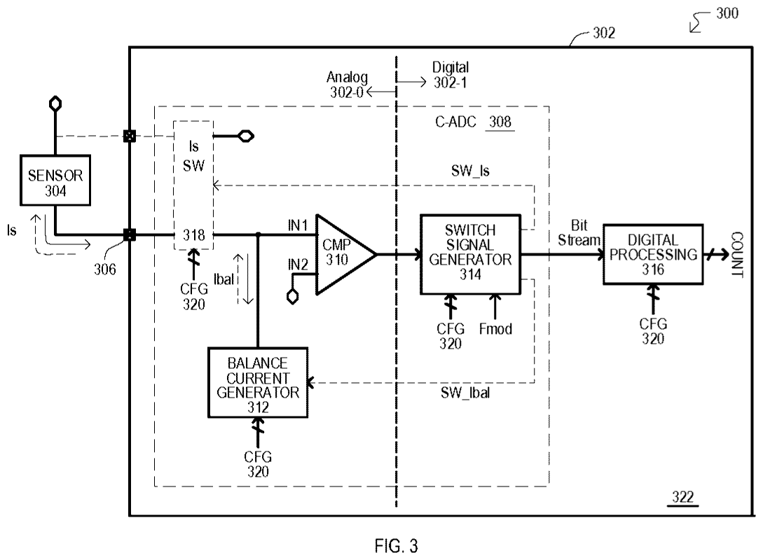

FIG. 3 is a diagram of a sensor system 300 according to an embodiment. A system 300 can include an ADC section 302 and a sensor 304. A sensor 304 can be any suitable sensor as described herein and equivalents. A sensor 304 can generate, or be charged and/or biased to generate, a sensor current (Is). A sensor current (Is) can flow from a sensor 304, into a sensor 304, or both in different phases of a sensing operation.

An ADC section 302 can include an analog section 302-0 and a digital section 302-1. An analog section 302-0 can include an analog comparator 310 and can include (or be configured to include) a balance current generator 312. In some embodiments, an analog section 302-0 can include a sense switching section 318. In some embodiments, ADC section 302 can be formed in an integrated circuit (IC) substrate 322. An analog comparator 310 can have an input (IN1) connected to receive a sensor current (Is) and an output connected to switch signal generator 314. A balance current generator 312 can generate a balance current Ibal. A balance current Ibal can flow in a direction opposite to that of sensor current (Is) with respect to input (IN1). In some embodiments, a balance current generator 312 can be modulated according to one or more balance switch control signals SW_Ibal.

In some embodiments, a sensor current (Is) can directly flow into or out of comparator input IN1. However, in other embodiments a sense switching section 318 can selectively connect a sensor current (Is) to analog comparator 310. In some embodiments, a sense switching section 318 can selectively connect a sensor 304 to a power supply in response to sense switch control signals SW_Is. Such a feature can enable a sensor current (Is) to modulated.

A digital section 302-1 can include a switch signal generator 314 and digital processing circuits 316. A switch signal generator 314 can generate switch control signals SW_Ibal and/or SW_Is in response to an output of analog comparator 310 and a modulation clock Fmod. An output of switch signal generator 314 can be a bit stream that varies according to a sensor current (Is). Digital processing circuits 316 can process a bit stream to generate a multi-bit output value COUNT.

A C-ADC circuit 308 can include analog comparator 310, balance current generator 312, switch signal generator 314, and optionally sense switch section 318. In some embodiments, C-ADC circuit 308 can be one version of those shown in FIGS. 1 to 2D.

In some embodiments, various portions of ADC section 302 can be configurable according to configuration inputs 320. Configuration inputs 320 can be provided from a configuration data stored in a memory (not shown). In some embodiments, switch elements within balance current generator 312 and sensor current switching section 318 can be connected in various configurations based on configuration inputs 320. A magnitude of a current provided by balance current generator 312 can be established by configuration inputs 320. A switch signal generator 314 can be configured based on configuration inputs 320. A switch signal generator 314 can include various digital blocks (e.g., flip-flops, other logic gates) interconnected based on configuration inputs 320. In addition or alternatively, programmable logic can be configured with configuration inputs 320 to form all or part of switch signal generator 314.

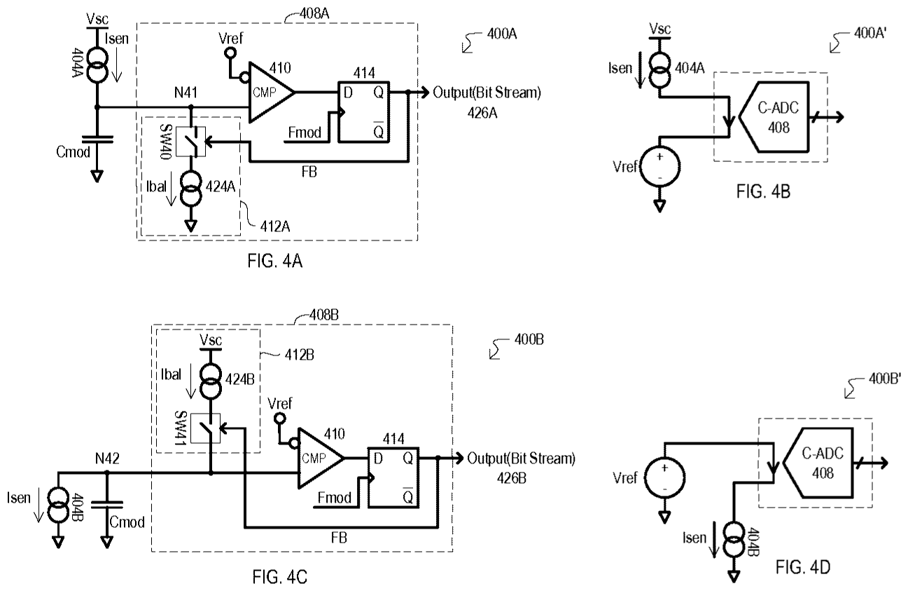

FIGS. 4A to 4D are schematic diagrams of capacitance sense architectures 400A/B according to embodiments that can convert a sensor current into an output bit stream, which can be subsequently converted into multi-bit digital values. In some embodiments, systems 400A or 400B can be implementations of system 300. FIG. 4A shows a source current measurement system 400A that includes a sensor current source 404A, a modulation capacitance C mod, and a C-ADC circuit 408A. A sensor current source 404A can correspond to a current generated by a sensor device. A modulation capacitance C mod can be connected in series with sensor current source 404A at input node N41. A value of C mod can be selected based on an expected sensor current.

A C-ADC circuit 404A can include an analog comparator 410, a balance current generator 412A, and a switch signal generator 414. Analog comparator 410 can have a first (+) input connected to node N41 and a second input (−) connected to a reference voltage Vref. A balance current generator 412A can include a current source 424A in series with a switch SW40 between node N41 and a low power supply node. In some embodiments, a current source 424A can be programmable with configuration data, or the like. Switch SW40 can be controlled according to a feedback signal FB. A switch signal generator 414 can include a D-Q type flip-flop (FF) 414 having an input (D) connected to an output of comparator 410, an output (Q) 426A that provides an output bit stream and serves as feedback signal FB. FF 414 can be clocked according to a periodic modulation clock signal Fmod.

In operation, as a sensor current Isen charges modulation capacitance C mod, a voltage at node N41 can rise. When the voltage exceeds Vref, an analog comparator 410 output can go high. As a result, FF output 426A can transition high. This can cause a balance current Ibal to discharge node N41 by operation of switch SW40. Once node N41 is discharged below Vref, an analog comparator 410 output can go low causing FF output 426A to transition low. This can stop balance current Ibal at node N41, enabling the C mod to charge in response to Isen. The process can repeat as a sensor current Isen continues to flow. According to the magnitude of sensor current Isen, a bit stream 426A duty cycle can vary. FIG. 4B is a diagram of a system 400A′ showing a simplified representation of the system of FIG. 4A.

FIG. 4C shows a sink current measurement system 400C that includes a sink current source 404B, a modulation capacitance C mod, and a C-ADC circuit 408B. A system 400C can operate in a similar fashion to FIG. 4A. A system 400C can differ from that of FIG. 4A in that a sensor current Isen can discharge C mod while a balance current generator 412B can charge C mod. FIG. 4D is a diagram of a system 400B′ showing a simplified representation of that shown in FIG. 4C.

In the embodiments of FIGS. 4A and 4C a maximum sensor current Isen can be lower than a balance current Ibal. A supply voltage Vsc can be higher than a reference voltage Vref.

A transfer function for the systems 400A and 400C can be given as:

$$D x = \frac{1}{Ibal} \cdot Isen$$

where Dx is a conversion result (e.g., digital value).

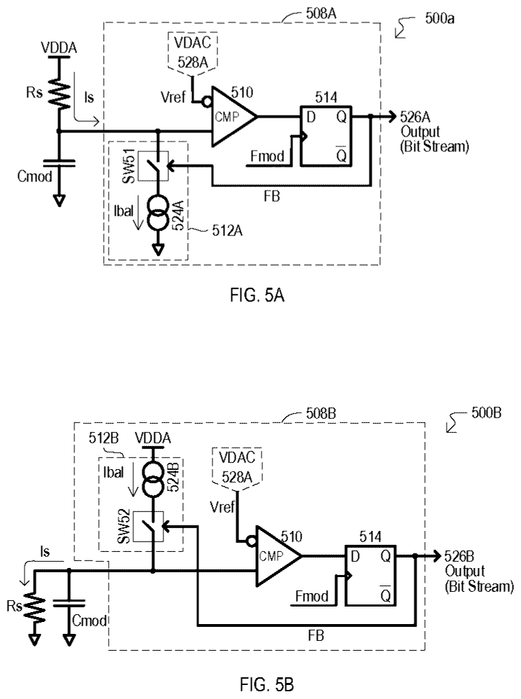

FIGS. 5A and 5B show how the current-to-digital conversion architecture of FIGS. 4A and 4C can be applied to resistance measurement applications, according to embodiments. FIGS. 5A and 5B have the same configuration as FIGS. 4A and 4C respectively, but with a sensor resistance Rs in place of a sensor current source 404A/B. Current sources 524A/B can be any of: a constant current source, a digitally programmable current source (iDAC), a resistance or a programmable resistance set. A transfer function of the conversions of FIGS. 5A and 5B can be given by:

$$D x = \frac{VDDA - Vref}{Ibal} \cdot \frac{1}{R s} ( FIG . 5 A )$$

$$Dx = \frac{Vref}{Ibal} . \frac{1}{R s} ( FIG . 5 B )$$

The embodiments of FIGS. 5A and 5B can operate optimally under the conditions:

$$\frac{VDDA - Vref}{R {s}_{min}} < Ibal ( FIG . 5 A )$$

$$\frac{Vref}{R {s}_{min}} < Ibal ( FIG . 5 B )$$

where Rsₘᵢₙ is a minimum resistance of Rs.

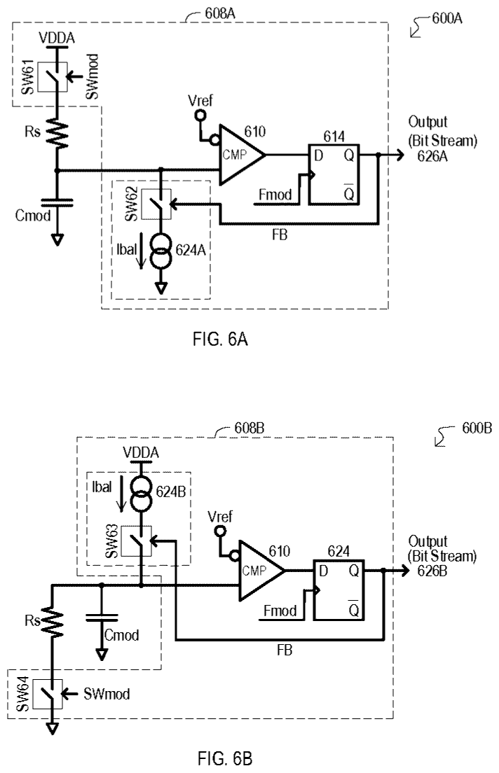

If a maximum sensor current (Is) is higher than a maximum balance current Ibal, a reference voltage Vref can be adjusted. Accordingly, in some embodiments a reference voltage Vref can be changed with a voltage digital-to-analog converter (VDAC) 528A/B. However, in other embodiments a modulation switch can be included in series with a sensor resistance Rs, to further control Is. Such embodiments are shown in FIGS. 6A and 6B.

FIGS. 6A and 6B show resistance measurement systems 600A and 600B according to additional embodiments. FIGS. 6A and 6B include architectures like those of FIGS. 5A and 5B, respectively, but include a switch SW61/SW64 in series with a sensor resistance Rs. Switches SW61/SW64 can be controlled with a periodic signal SW mod having a duty cycle D mod. In such an arrangement, operations may be optimal under the conditions:

$$\frac{VDDA - Vref}{R {s}_{min}} \cdot Dmod < Ibal ( FIG . 6 A )$$

$$\frac{Vref}{R {s}_{min}} \cdot Dmod < Ibal ( FIG . 6 B )$$

While embodiments like those of FIGS. 6A and 6B can accommodate greater maximum sensor current values, a resulting transfer function can have a digital value that is inversely proportional to sensor resistance.

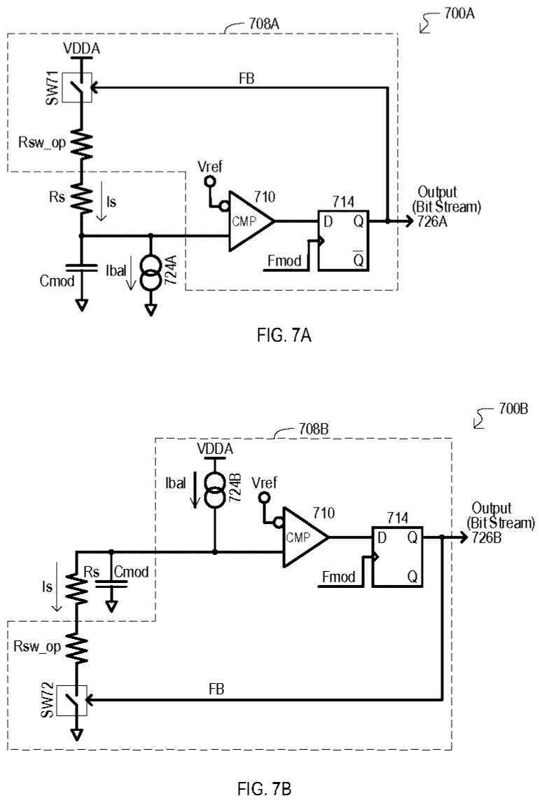

FIGS. 7A and 7B show resistance measurement systems 700A and 700B according to additional embodiments. The architecture of FIGS. 7A and 7B can include items like those of FIGS. 6A and 6B. However, FIGS. 7A and 7B do not include a switch in series with a current source 724A/724B. Rather, a switch (SW71/SW72) can be included that is in series with sensor resistance Rs to modulated a sensor current (Is) according to analog comparator output 726A. Further, FIGS. 7A and 7B include switch resistance values (Rs_op).

A transfer function for embodiments like those of FIGS. 7A and 7B can be given by:

$${D}_{x} = \frac{Ibal}{VDDA - Vref} \cdot Rs ( FIG . 7 A )$$

$${D}_{x} = \frac{Ibal}{Vref} \cdot Rs ( FIG . 7 B )$$

Further, the embodiments may operate optimally under the conditions:

$$\frac{VDDA - Vref}{R {s}_{max}} > Ibal ( FIG . 7 A )$$

$$\frac{Vref}{R s} > Ibal ( FIG . 7 B )$$

In some embodiments, a switch resistance (Rsw_op) can be included as part of Rs.

From the above transfer function it can be see that an output value Dx can be directly proportional to a sensor resistance Rs.

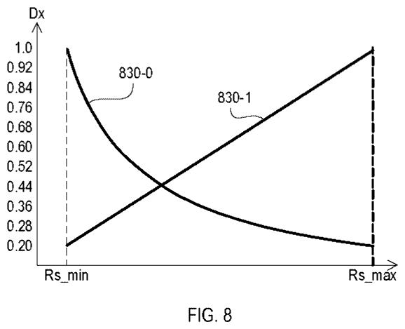

FIG. 8 is a graph comparing responses of systems like those of FIGS. 6A/B and 7A/B. Response 830-0 shows a non-linear response for an embodiment like that of FIGS. 6A and 6B. Response 830-1 shows a linear response for an embodiment like that of FIGS. 7A and 7B.

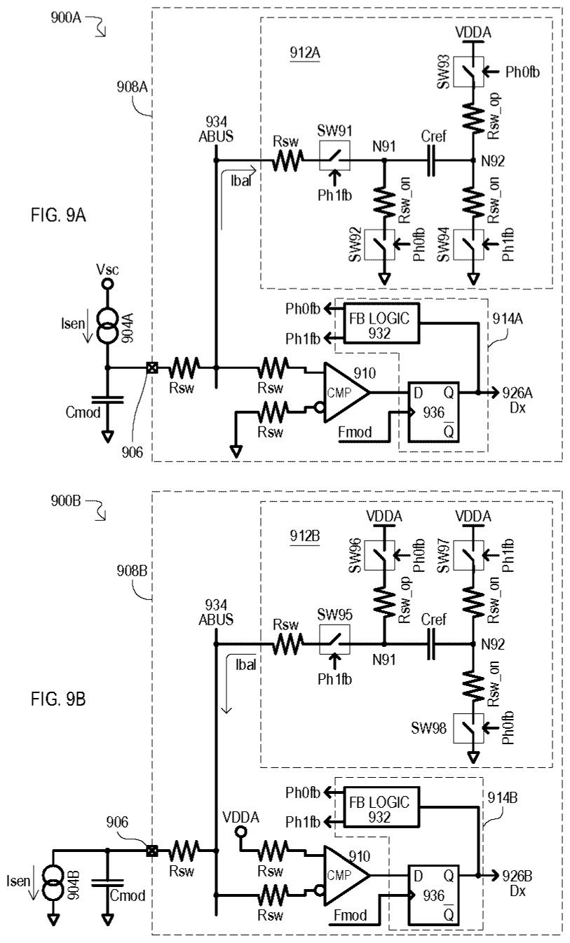

While embodiments like those shown in FIGS. 3 to 7B can include a reference voltage source and IDAC (e.g., for a balance current source), other embodiments can employ switched capacitor (SC) circuits for such circuit operations. FIGS. 9A and 9B are schematic diagrams showing such embodiments.

FIGS. 9A and 9B show current measuring systems 900A/900B that include SC balance current sources. FIGS. 9A and 9B show various resistance values Rsw. In some embodiments, such resistance values correspond to configurable analog switches enabled with configuration inputs to provide signal paths. Resistance values Rsw_on correspond to resistance values for corresponding switches in their conducting state.

FIG. 9A shows a system 900A for sensing a sensor current source according to an embodiment. A system 900A can include a sensor current source 904A, modulation capacitor C mod, and C-ADC circuit 908A. A sensor current source 904A can represent a sensor current Isen provided by a sensor device. A sensor current Isen can vary according to sensor operation. A capacitance C mod can be selected based on an expected sensor current range and/or balance current range.

A C-ADC circuit 908A can include an analog comparator 910, a SC balance current generator 912A, and a switch signal generator 914A. Analog comparator 910 can have a first input (+) connected to sensor current source 904A and C mod and a second input (−) to a low power supply node (e.g., ground). SC balance current source 912A can include switches SW91 to SW94 and reference capacitance Cref. Switch SW91 can connect a first node N91 of Cref to the first input of analog comparator 910 and can be controlled by a signal Ph1fb. Switch SW92 can connect a first node N91 to a lower power supply node, and can be controlled by a signal Ph0fb. Switch SW93 can connect a high power supply node (VDDA) to a second terminal N92 of Cref and be controlled by signal Ph0fb. Switch SW93 can connect a low power supply node to the second terminal N91 and be controlled by a signal Ph1fb.

Switch signal generator 914A can include a DQ FF 936 and feedback (FB) logic 932. An output of analog comparator 910 can be connected to an input (D) of FF 936. An output (Q) of FF 936 can provide a bit stream output signal 926A, and can also be an input of FB logic 932. FF 936 can operate based on a modulation clock signal Fmod. FB logic 932 can generate switch control signals Ph0fb and Ph1fb that are active according to an output of analog comparator 910, and can have active levels that are non-overlapping in time.

In operation, a sensor current Isen can be sourced to charge C mod. Once a voltage on C mod rises above a voltage at the (−) input of analog comparator 910 (which can be about ground depending on resistance Rsw and any offset voltage), an output of comparator 910 can be driven high. This can activate switch control signals Ph0fb/Ph1fb. By switched capacitor action, node N92 can be charged toward VDDA then coupled to ground. Switch SW91 can be enabled, causing a sink balance current (Ibal) to flow that will serve to offset the sensor current Isen at the (+) input of analog comparator 910. When a voltage at the (+) input of analog comparator falls below that of the (−) input, signals Ph0fb and Ph1fb can be disabled, stopping a balance current Ibal. Isen can then begin charging C mod once again.

It is noted that balance current generator 912A can be conceptualized as a switch capacitor resistor. As such, it can be configured to provide a balance current Ibal that depends on a modulating frequency Fmod and reference capacitance, and not upon a switch parasitic resistance (e.g., Rsw, Rsw_on).

In some embodiments, C-ADC circuit 908A can be part of an IC device that is separate from sensor current source 904A and C mod. Sensor current source 904A and C mod can be connected to such an IC device at an external connection 906. In some embodiments, C-ADC circuit 908A can include an analog bus 934, which can be a low resistance bus for analog signals that can be connected to circuit elements by configurable switches (represented by switch resistances Rsw). In some embodiments, a reference capacitance Cref can be a programmable capacitance of the IC device. However, in other embodiments, a reference capacitance Cref can be external to the IC device (i.e., connected via an external connection).

FIG. 9B shows a system 900B for sensing a sensor current source according to another embodiment. A system 900B can include items like those of FIG. 9A but can operate with a sensor current source 904B that sinks a current from C mod.

In operation, a sensor current Isen can sink current from C mod. Once a voltage on C mod falls below a voltage an the (+) input of analog comparator 910 (which can be about VDDA depending on resistance Rsw and any offset voltage), an output of comparator 910 can be driven high, activating switch control signals Ph0fb/Ph1fb. By switched capacitor action, a balance current Ibal can be generated. As a result, a sourcing balance current (Ibal) can flow to the (−) input of analog comparator 910. When a voltage at the (−) input rises above that of the (+) input, signals Ph0fb and Ph1fb can be disabled, stopping a balance current Ibal. Isen can then begin discharging C mod once again.

Embodiments of FIGS. 9A and 9B can have a transfer function given by:

$$D x = \frac{1}{VDDA \cdot Cref \cdot fmod} \cdot Isen$$

Embodiments like those of FIGS. 9A and 9B may operate optimally when a maximum sensor current Isen is less than a balance current Ibal. Further, it is desirable for an analog comparator to have a “rail-to-rail” operation (i.e., be able to switch when inputs are near high or low power supply levels).

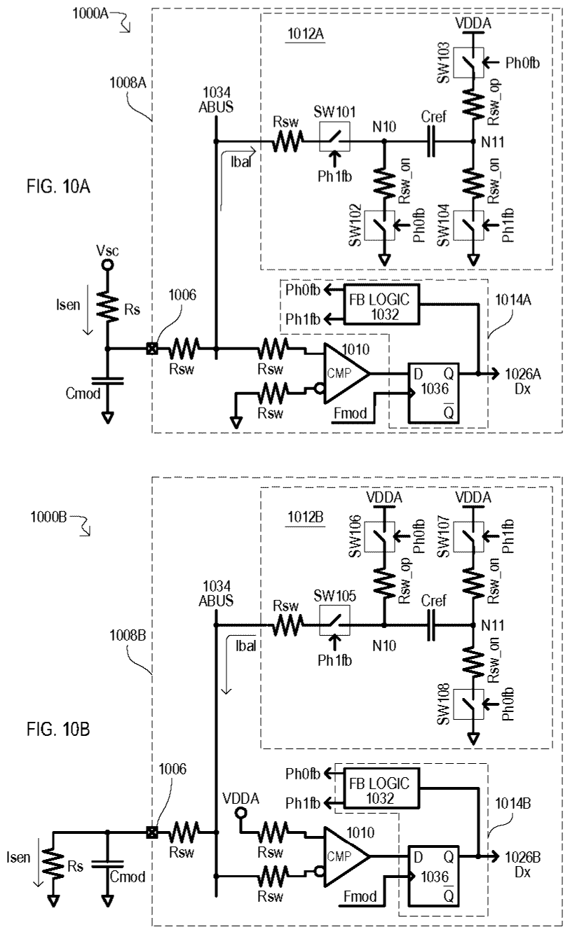

While FIGS. 9A and 9B show embodiments configured to convert a current from a sensor device, the same architecture can be advantageously applied to resistance sensing. FIGS. 10A and 10B are schematic diagram showing such embodiments.

FIGS. 10A and 10B show resistance measuring systems 1000A/1000B that include SC balance current sources. FIGS. 10A and 10B include the same architectures as FIGS. 9A and 9B, but with a sensor resistance Rs in place of a sensor current sources 904A/B. Accordingly, the operation of systems 1000A/B are understood with reference to FIGS. 9A/B.

The embodiments of FIGS. 10A and 10B can have a transfer function given by:

$$D x = \frac{1}{Cref \cdot fmod} \cdot \frac{1}{R s}$$

Advantageously, such a transfer function shows that conversion results are not influenced by VDDA. Accordingly, such embodiments can flexibly accommodate various power supply levels.

Embodiments of FIGS. 10A and 10B may operate optimally under the condition:

$$\frac{1}{Cref \cdot fmod} < R {s}_{max}$$

where Rsₘₐₓ is a maximum expected resistance for Rs.

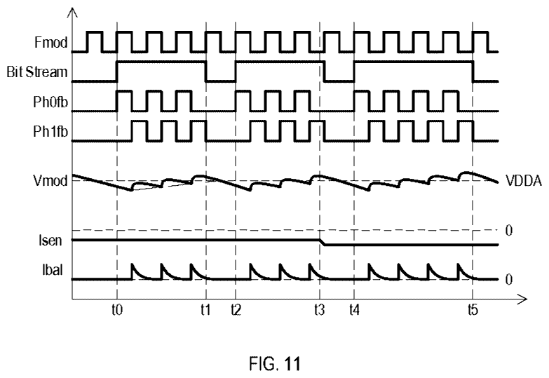

FIG. 11 is a timing diagram showing operations of a sensor current sinking embodiment, like that of FIG. 10B. FIG. 11 includes the following waveforms: a modulation clock (Fmod); an output bit stream (Bit Stream); switch control signals (Ph0fb, Ph1fb); a voltage on a modulation capacitance (V mod); a sensor current Isen; and a generated balance current (Ibal).

Prior to time t0, a Isen can flow, discharging C mod, resulting in V mod dropping from VDDA.

At time t0, V mod can drop below VDDA, causing an output of analog comparator to go high. As a result, feedback logic can generate non-overlapping switch control signals Ph0fb/Ph1fb, which can be synchronous with Fmod. By operation of switched capacitor action, balanced current generator can generate Ibal which acts against Isen at C mod. Consequently, V mod can begin to rise as Ibal counteract Isen.

At time t1, V mod can rise above VDDA, causing an output of analog comparator to go low. As a result, switch control signals Ph0fb/Ph1fb can be disabled, ending the generation of Ibal. Isen can continue to flow, so V mod can begin falling once again.

Times t2 to t3 can operate in the same fashion as times t0 to t1, and can represent a conversion result of Isen with Bit Stream being high for three Fmod cycles.

At time t3, a sensor resistance can decrease. As a result, Isen can increase (in the negative direction).

At time t4, V mod can drop below VDDA, activating switched capacitor Ibal generator. However, because Isen had increased, it takes Ibal four clock cycles to drive V mod back up to VDDA.

Times t4 to t5 can represent conversion result of the higher Isen level, with Bit Stream being high for four Fmod cycles.

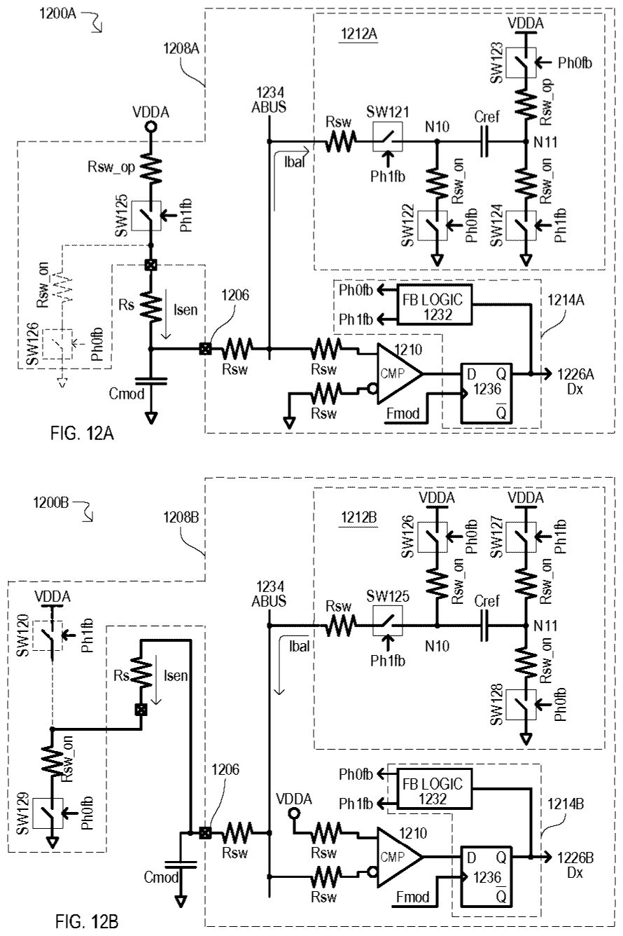

While embodiments like those of FIGS. 10A and 10B can provide resistance sensing with corresponding advantages, it may be desirable to provide a conversion with a more linear relationship with respect to a sensor resistance. Such embodiments are shown in FIGS. 12A and 12B.

FIGS. 12A and 12B show resistance measuring systems 1200A/1200B that include SC balance current sources. FIGS. 12A and 12B include the same architectures as FIGS. 10A and 10B, but with the addition of a switch (SW125, SW129) in series with the sensor resistance Rs. Such a switch (SW125, SW129) can be modulated with a switch control signal Ph1fb. Optionally, systems 1200A/B can further include a second additional switch (SW126, SW120) that can bypass a power supply for the sensor resistance Rs.

Systems 1200A and 1200B can operate as described for systems 900A and 900B, respectively, but with the addition of switches SW125/SW129. In system 1200A, while a C mod potential remains below the (−) input of analog comparator 1210, Isen can flow. Once a C mod potential rise above the (−) input potential, Ibal can be generated as described for FIG. 9A. However, in addition, on Ph1fb phases, by operation of SW125 Rs can be isolated from VDDA, and Isen can stop flowing. Optionally, on Ph0fb phases, by operation of SW126, the Rs terminal opposite to that connected to C mod can be connected to a low power supply (e.g., ground). Consequently, a sensor output potential can remain at about the same operating voltage during a sensing operation.

In system 1200B, while a C mod potential remains above the (+) input of analog comparator 1210, Isen can flow, discharging C mod. Once a C mod potential falls below a (+) input potential, Ibal can be generated. In addition, on Ph0fb phases, by operation of SW129 Rs can be isolated from a low power supply potential, and Isen can stop flowing. Optionally, on Ph1fb phases, by operation of SW120, the Rs terminal opposite to that connected to C mod can be connected to a VDDA.

The embodiments of FIGS. 12A and 12B can have a transfer function given by:

$$D x = Cref \cdot fmod \cdot Rs$$

Embodiments of FIGS. 12A and 12B may operate optimally under the condition:

$$\frac{1}{Cref \cdot fmod} > R {s}_{max}$$

Advantageously, the transfer function for FIGS. 12A/B shows a linear dependence upon Rs. As in the case of the embodiments of FIGS. 10A and 10B, conversion results are not sensitive to variations in a power supply voltage (VDDA). A sensitivity and resolution can be varied over a wide range by adjusting Ibal through Fmod and/or FB logic.

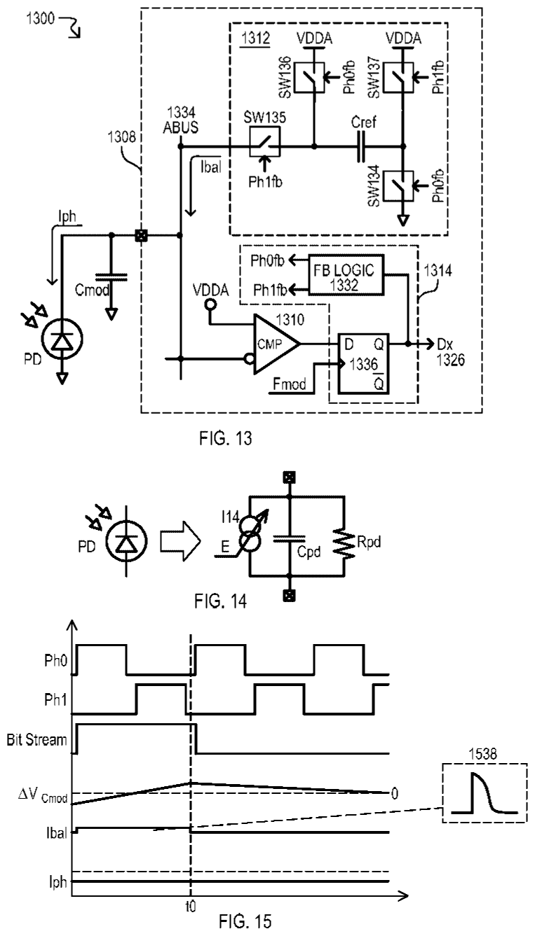

While embodiments can include any suitable current sensing application, some embodiment can include photosensing systems. According to embodiments, a current generating photosensing device, such as a photodiode, can have a current measured with a C-ADC circuit as described herein. Such a system can enjoy a wide variety of applications, including but not limited to: optical proximity detection, motion detection, light intensity detection, and a smoke alarm. FIG. 13 shows such an embodiment.

FIG. 13 is a schematic diagram of a photosensing system 1300 according to an embodiment. FIG. 13 includes the same general architecture as FIG. 9B, but with a photodiode PD in place of a sensor current sources 904B.

FIG. 14 shows a photodiode equivalent circuit. In response to incident light, a photodiode can generate a photocurrent Iph. Accordingly, the operation of system 1300 is understood with reference to FIGS. 9B, where a photo diode operates as a light dependent current source, such as that shown in FIG. 14.

The embodiment of FIG. 13 can have a transfer function given by:

$$D x = \frac{1}{VDDA \cdot Cref \cdot fmod} \cdot Iph$$

The embodiments of FIG. 13 may operate optimally under the condition:

$$VDDA \cdot Cref \cdot fmod > {Iph}_{max}$$

where Iphₘₐₓ is an expected maximum current from PD.

FIG. 15 is a timing diagram showing an operation of an embodiment like that of FIG. 13. FIG. 15 includes the following waveforms: a phase signal Ph0 (Ph0fb can be a logical ANDing of Bit Stream and Ph0); a phase signal Ph1 (Ph1fb can be a logical ANDing of Bit Stream and Ph1); an output bit stream (Bit Stream); a change in a voltage on a modulation capacitance (ΔV_{Cmod}); a generated balance Ibal; and a generated photodiode current (Iph).

Prior to time t0, Iph can have discharged C mod, resulting in bit stream going high. As a result, Ibal can be active, which can take the form of pulses as shown by 1538.

At time t0, Ibal can charge C mod above the voltage at the (+) input of the analog comparator, disabling Ibal. As a result, Iph can discharge C mod.

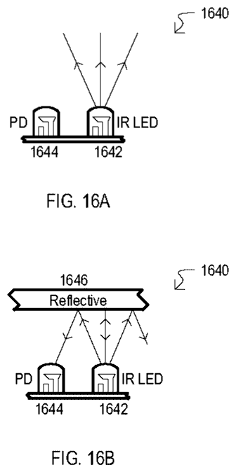

Embodiments can include various other photosensing applications, including proximity detection using a sensor that includes a light source and corresponding light detector. FIGS. 16A and 16B are diagrams showing a proximity sensor 1640 that can be included in embodiments. A proximity sensor 1640 can include a light source 1642, which can be a light emitting diode (LED), and a light detector 1644 which can be a PD. FIG. 16A shows sensor 1640 while an object is outside of a detection proximity. A light source 1642 can emit light that is not detected by light detector 1644. FIG. 16B shows sensor 1640 when an object is within a detection proximity. A light source 1642 can emit light that is reflected by a reflective surface 1646 of an object. The reflected light is sensed by PD 1644, which can generate a photocurrent.

While embodiments herein can include single-ended systems, in which a sensed current generates an input signal at one input of an analog comparator, embodiments can also include differential systems, in which sensor currents generate inputs at both inputs of an analog comparator.

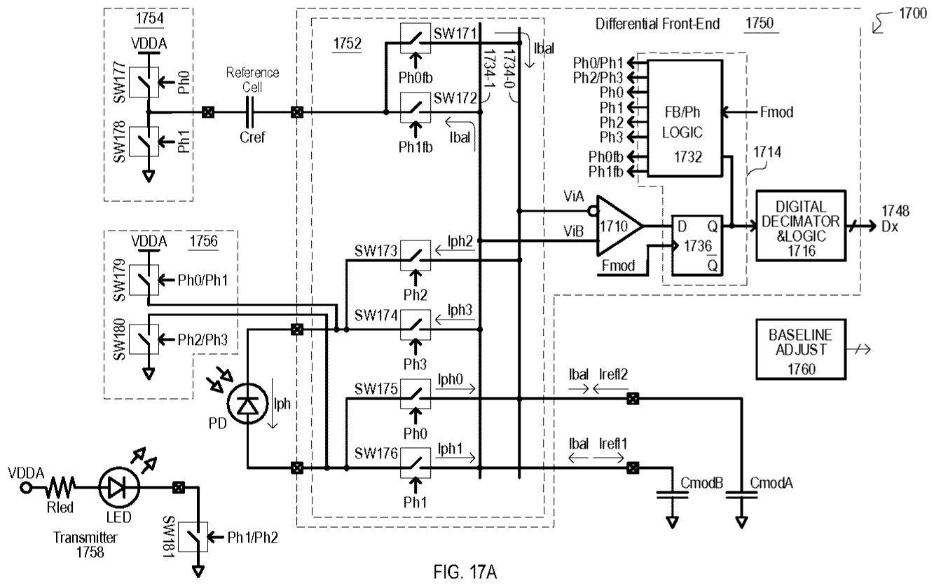

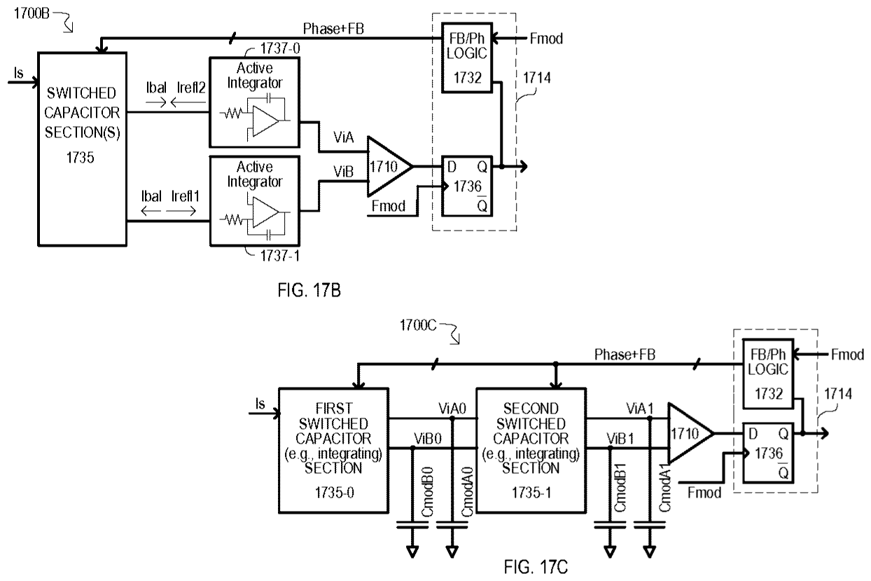

FIG. 17A is a schematic diagram of a proximity sensing system 1700A according to an embodiment. A system 1700A can include a transmitter 1758, a detector PD, a differential front-end 1750, a reference switching section 1754, a detector switching section 1756, and baseline adjust circuits 1760.

A transmitter 1756 can include an LED, resistance Rled, and a switch SW181 connected in series. LED can emit light in one or more frequency ranges that are detectable by PD. SW181 can enable a current path through LED (and thus the emission of light) in response to a switch control signal Ph1/Ph2. PD can be a photodiode in a reverse bias configuration that can generate a current Iph in response to incident light from the LED.

A differential front-end 1750 can include an analog comparator 1710, switch signal generator 1714, digital processing circuits 1716, and a bridge switch section 1752. Analog comparator 1710 can have one input (+) connected to a first modulation capacitance C mod B, and the other input (−) connected to a second modulation capacitance C mod A. Switch signal generator 1714 can include a DQ FF 1736 clocked by Fmod arranged as in other embodiments, to generate a bit stream in response to an output from analog comparator 1710. An output of FF 1736 can be provided as an input to FB and phase (FB/Ph) logic 1732 and an input to digital processing circuits 1716. Phase and feedback logic 1732 can generate a number of switch control signals that will be described in more detail herein. Digital processing circuits 1716 can generate a multi-bit digital value from a bit stream output from FF 1736 according to any suitable manner. In some embodiments, digital processing circuits 1716 can include a digital decimator circuit, as well as digital filters.

A bridge switch section 1752 can include pairs of switches SW171/SW172, SW173/SW174, SW175/SW176 having first terminals commonly connected to one another, and second terminals connected to first and second analog buses 1734-0/1734-1, respectively. Switch pair SW171/SW172 can have a common node connected to a reference capacitance Cref. Switch pair SW173/SWW174 can have a common node connected to a first terminal of PD. Switch pair SW175/SWW176 can have a common node connected to a second terminal of PD. Analog bus 1734-0 can be connected to a modulation capacitance C mod B. Analog bus 1734-1 can be connected to a modulation capacitance C mod A.

A reference switching section 1754 can include a switches SW177 and SW178. SW177 can be connected between a high power supply VDDA and Cref, and can be controlled by signal Ph0. Switch SW178 can be connected between a low power supply (e.g., ground) and Cref, and can be controlled by signal Ph1.

A detector switching section 1756 can include a switches SW179 and SW180. SW179 can be connected between a high power supply VDDA and a first terminal of PD, and can be controlled by signal Ph0/Ph1. Switch SW180 can be connected between a low power supply and a second terminal of PD, and can be controlled by signal Ph2/Ph3.

Baseline adjust circuits 1760 can generate a baseline value B, which can be combined with a raw count value Dx to account for changing parameters, as will be described at a later point herein. In some embodiments, baseline adjust circuits 1760 can be a set of instructions executed by a processor in response to sensed conditions (e.g., temperature, VDDA level, background light).

While embodiments can include passive integrator architectures, other embodiments can include active integrators. FIG. 17B is a block schematic diagram of a system 1700B having active integrators. A system 1700B can be a differential sensing system like that of FIG. 17A, including a switched capacitor section 1735 that can generate sense and balance currents (Is, Ibal) according to embodiments disclosed herein. Unlike FIG. 17A, system 1700B can include active integrators 1737-0/1 for integrating voltages at input nodes to comparator 1710. Active integrators 1737-0/1 can take any suitable form, according to expected application.

While FIG. 17B shows a differential architecture with active integrators, embodiments can also include single-ended architectures with active integrators.

While embodiments can include single integrator and difference stages, other embodiments can include higher order modulation architectures. FIG. 17C is a block schematic diagram of a system 1700C having a higher order of modulations. A system 1700C can be a differential sensing system like that of FIG. 17A. However, unlike FIG. 17A, a system 1700C can multiple switched capacitor stages 1735-0/1, each operating to integrate a modulation capacitance, and apply a difference value in response to a quantization stage (e.g., comparator 1710). While FIG. 17C shows second order modulation, other embodiments can include higher orders of modulation. As in the case of FIG. 17B, single-ended systems can also include higher orders of modulation.

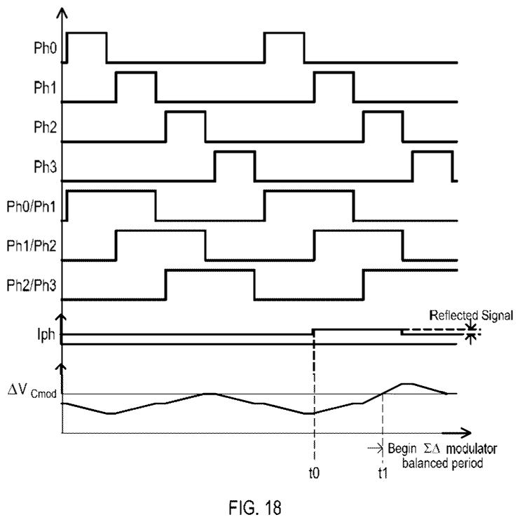

FIG. 18 is a timing diagram showing operations of a system 1700A. FIG. 18 includes the following waveforms: a switch control signals Ph0, Ph1, Ph2, Ph3, Ph0/1, Ph2/3; photocurrent Iph; and a differential voltage between a modulation capacitances C mod A/C mod B (ΔV_{Cmod}). Switch control signals Ph0fb and Ph1fb (not shown in FIG. 18) are understood to be generated by a logical ANDing of the output of analog comparator 1710 and signals Ph0 and Ph1, respectively.

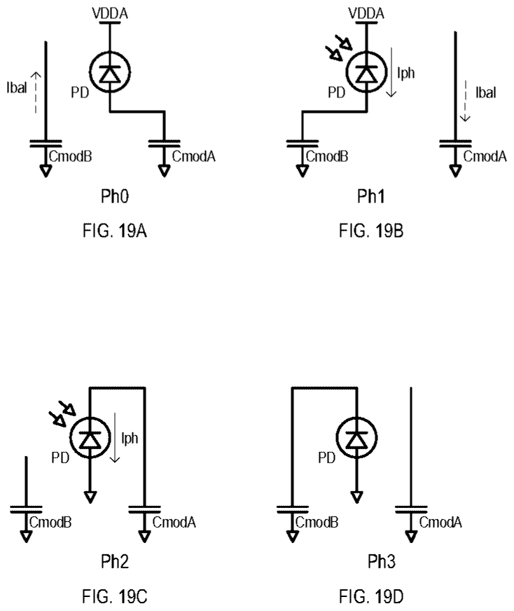

Referring back to FIG. 17A in conjunction with FIGS. 19A to 19D, a sensing operation according to an embodiment will be described. A sensing operations can occur in four phases, shown in FIGS. 19A to 19D. The four phases include Ph0, Ph1, Ph2 and Ph3 (examples of which are shown in FIG. 18). In a sense operation, a differential voltage can be generated across the inputs of analog comparator 1710. A voltage on C mod A (ViA) can be applied at a (−) input. A voltage on C mod B (ViB) can be applied at a (+) input. In some embodiments, a voltage on modulation capacitances C mod A and C mod B can be initialized to a same level (e.g., VDDA/2) prior to sensing operations.

In Ph0, by operation of switches SW179 and SW175, PD can be connected to VDDA in series with C mod A. At this time, transmitter 1758 is not enabled, so no photocurrent beyond that of any ambient light will contribute to the charging of C mod A. In the event a sufficient differential voltage exists at the input of analog comparator 1710 (ViB>ViA), by operation of SW172, an Ibal sink current can discharge C mod B (working against a voltage differential created by a photocurrent Iph).

In Ph1, by operation of switches SW176 and SW179, PD can be connected to VDDA in series with C mod B. In addition, within transmitter 1758, SW181 can enable LED. If light from the LED is detected (e.g., due to a reflecting object in proximity, and shown by arrows in the figure), PD can generate a photocurrent (Iph+Irefl1). Such a current can charge C mod B, increasing ViB. In the event a sufficient differential voltage exists at the input of analog comparator 1710 (ViB>ViA), by operation of SW171, an Ibal source current can charge C mod A (working against a voltage differential created by Iph).

In Ph2, by operation of switches SW180 and SW173, a PD can have an anode connected to a low power supply and a cathode connected to C mod A. At this time, LED can be enabled by SW181. If light from the LED is detected (shown by arrows in the figure), PD can generate a photocurrent (Iph+Irefl2) that sinks current from C mod A, decreasing ViA.

In Ph3, by operation of switch SW175, a PD can have cathode connected to C mod B. An anode of PD can be connected by ground by operation of switch SW180. At this time, the LED is disabled by operation of switch SW181.

In this way, if little or no additional photocurrent (Iph) is generated due to LED, C mod A and C mod B can be charged to the same essential potential in phases Ph0 and Ph1. However, if a sufficient Iph is generated in Ph1, a differential voltage will be generated, with ViB>ViA. Similarly, in phases Ph2 and Ph3, if little or no additional Iph is generated, C mod A and C mod B can be discharged to the same essential potential. However, if a sufficient Iph is generated in Ph2, a differential voltage will be generated, with ViB>ViA.

Once a differential voltage (ViB−ViA) is sufficient for analog comparator 1710 to drive its output to an opposite level (i.e., a feedback active level), a balance current Ibal can be generated. If feedback is active during Ph0, a balance current Ibal can sink current from C mod B. If feedback is active during Ph1, a balance current Ibal can source current to C mod A. The balance currents thus work to reduce any differential voltage created by Iph.

Referring once again to FIG. 18, prior to time t0, photocurrent Iph is at a non-detection level (e.g., background light). As a result, a differential voltage ΔV_{Cmod} operates in balanced state, C mod A and C mod B charging and discharging essentially the same amount of current.

At time t0, Iph increases, indicating the detection of reflected light. As a result, the differential voltage triggers the analog comparator, which drives its output to an active level.

At time t1, a balance current circuit is enabled to generate a balance current that tends to reduce ΔV_{Cmod}. Such an operation can be conceptualized as a EA modulation period, as generation of the balance current can operate like a feedback signal of a EA modulator circuit.

In this way, differential sigma-delta modulator operation can detect a voltage difference and compensates for this difference using a balancing current. It is noted in differential architectures according to embodiments, ambient light can be a common mode value. As shown in FIG. 18, in the first two phases (i.e., Ph0/Ph1), a voltage on C mod A and C mod B can increase by the same amount. In the second two phases (i.e., Ph2/Ph3), a voltage on C mod A and C mod B can decrease by the same amount. Thus, an overall ΔV_{Cmod} from the ambient light is zero. A balance current can be generated by a switched capacitor circuit that includes a reference capacitor Cref and four analog switches (SW171, SW172, SW177, SW178). By operation of FB/Ph logic 1732, the switched capacitor circuit can be clocked by an Fmod clock signal that can have a much higher frequency than the sensor stimulation signal frequency (i.e., Ph1/Ph2). A variation of the duty cycle of the sigma-delta modulator output signal (i.e., output of analog comparator 1710) indicates variations in LED reflected light.

The embodiment of FIG. 17A can have a transfer function given by:

$$DC = \frac{Irefl}{Cref \cdot VDDA \cdot Fmod} + B$$

$$RawData = DC \cdot ( {2}^{n} - 1 )$$

where DC is an average duty cycle of an output signal (i.e., output of FF 1736); n is a resolution of the digital processing circuit 1716; Irefl is the PD photocurrent contributed by reflected light; Fmod is the modulator frequency; and B is baseline value. RawData can be a value Dx. Baseline value B can vary according to an offset voltage of analog comparator 1710, mismatch between modulator capacitances (C mod A, C mod B), the value of Cref, VDDA, Fmod and temperature. It is noted that baseline value B can depend on slowly changing parameters and conditions.

Embodiments like those of FIG. 17A can reduce DC and low frequency currents in a detector PD. Further, embodiments can generate a modulated transmission signal (e.g., LED with Ph1/Ph2) that can be synchronously demodulated at the detector (Ph1/Ph2).

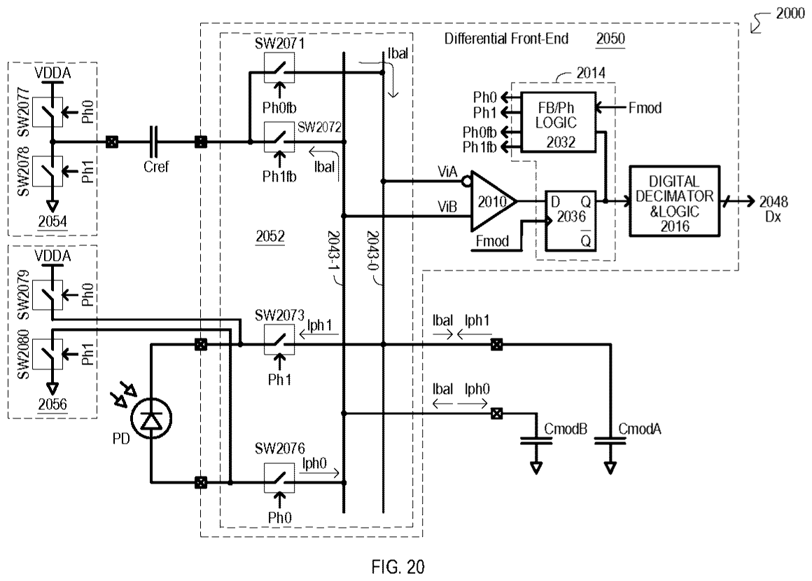

A differential sensing architecture like that of FIG. 17A can be employed for any suitable sensor type as described herein. FIG. 20 shows a light intensity sensing system 2000 with a differential front end according to an embodiment.

A system 2000 can include items like those of FIG. 17A, and their operation is understood from the description of FIG. 17A. Differences between FIG. 20 and FIG. 17A include a sensing operation that is a two-phase operation instead of a four phase operation. Accordingly, FB/Ph logic 2032 does not generate Ph2, Ph3 and related signals.

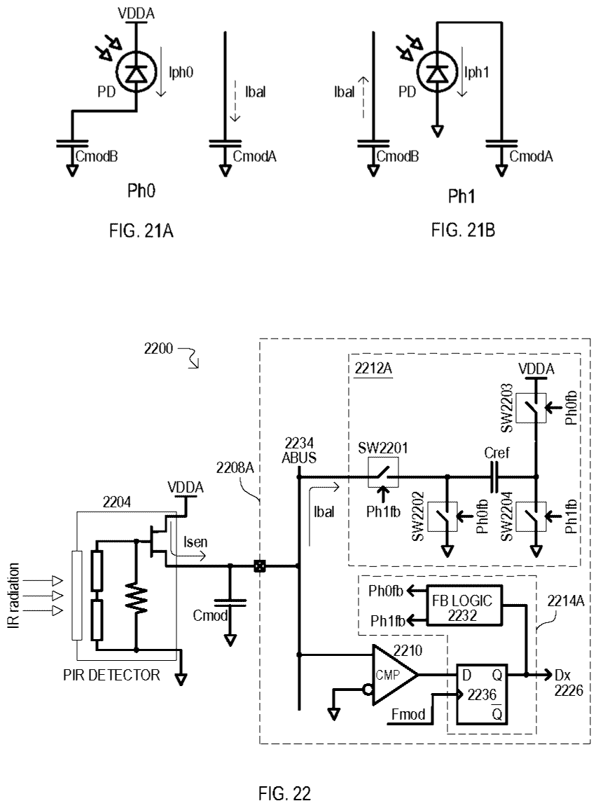

FIGS. 21A and 21B show sense operations for an embodiment like that of FIG. 20. FIG. 21A shows a first phase Ph0. FIG. 21B shows a second phase Ph1. As in the case of FIG. 17A, prior to sensing operations, capacitances C mod A and C mod B can be initialized to a same value (e.g., VDDA/2).

In Ph0, by operation of switches SW2076 and SW2079, an anode of PD can be connected to C mod B and a cathode of PD connected to VDDA. According to the amount of light detected, PD can generate a photocurrent (Iph0). Such a current can charge C mod B, increasing ViB. In the event a sufficient differential voltage exists at the input of analog comparator 2010, by operation of SW2072, a balance current Ibal can be generated that sources current to C mod A (working against a voltage differential created by PD photocurrents).

In Ph1, by operation of switches SW2080 and SW2073, a PD can have an anode connected to a low power supply and a cathode connected to C mod A. According to detected light, PD can generate a photocurrent (Iph1) that sinks current from C mod A, decreasing ViA. In the event a sufficient differential voltage exists at the input of analog comparator 2010, by operation of SW2071, a balance voltage Ibal can sink current from C mod B (working against a voltage differential created by a photocurrent).

It is understood from the descriptions of FIGS. 17 to 21B, that embodiments can include differential front ends for use with any other suitable sensor device.

FIG. 22 is a block schematic diagram of PIR detector system 2200 according to an embodiment. A PIR detector system 2200 can use a PIR sensor 2204 for motion sensing or the like. A PIR sensor 2204 can be configured to detect infrared radiation typically emitted by the human body (e.g., 6-14 μm wavelengths).

A system 2200 can include items like those of FIG. 10A, and their operation is understood from the description of FIG. 10A. FIG. 22 differs from FIG. 10A in that a C-ADC circuit 2208 can receive a sensor current from a PIR sensor 2204 instead of a sensor resistance Rs. In response to sensing the target IR radiation, PIR sensor 2204 can generate a current Isen. When Isen charges C mod high enough to cause analog comparator 2210 output to go high, enabling the generation of a balance current Ibal by switched capacitor action.

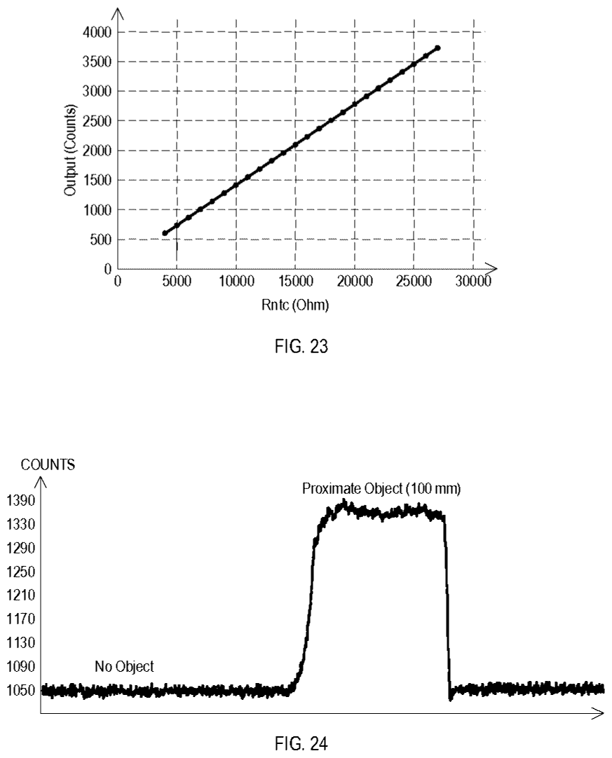

FIG. 23 is a graph showing sensing results for an embodiment like that of FIGS. 10A and 10B. The graph shows output count values versus a sensor resistance (Rntc) value. As shown, a count value can have an essentially linear relationship to a sensed resistance.

FIG. 24 is a graph showing proximity sensing results for an embodiment like that of FIG. 17A. When an object is not in proximity, a count value can be lower (i.e., about 1050). When an object is in proximity, in this example 100 mm, a reflected light can increase a count value to about 1360, detecting the object.

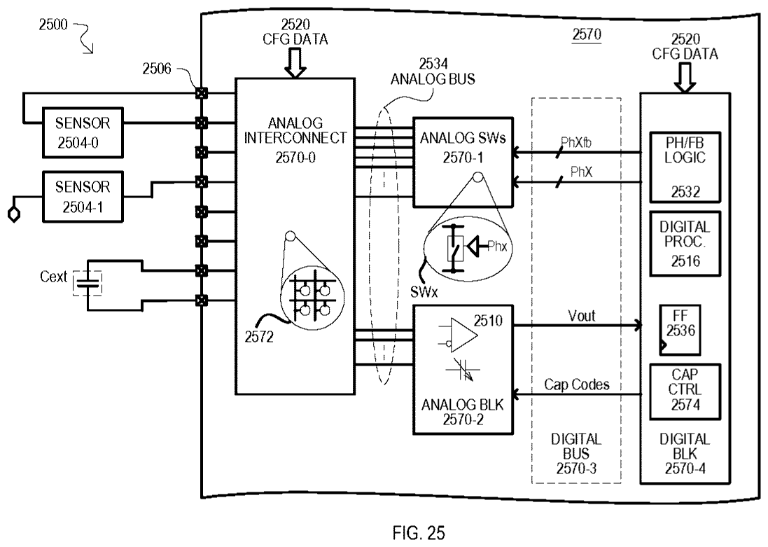

Embodiments can take any suitable circuit form, however, some embodiments can include an IC device, such as a system-on-chip (SoC) that is configurable to accommodate various different sensor types and sensor architectures. In some embodiments an IC device can be a mixed signal SoC having configurable analog and digital circuits. FIG. 25 is a block diagram of such an embodiment.

FIG. 25 is a block diagram of a system 2500 according to an embodiment. A system 2500 can include an IC device 2570 that can connect to various sensors (two shown as 2504-0, 2504-1). IC device 2570 can be configurable in response to configuration data 2520.

IC device 2570 can include analog interconnect 2570-0, configurable analog switches 2570-1, and configurable analog circuit block 2570-2 in communication with one another over an analog bus system 2534. IC device 2532 can also include configurable digital blocks 2570-4 which can be connected to configurable programmable analog switches 2570-1 and configurable analog circuit block 2570-2 by a digital bus system 2570-3.

Analog interconnect 2570-0 can be coupled to external connections (one shown as 2506) and can include a matrix formed of programmable connections (a portion shown as 2572). Interconnections can be established within analog interconnect 2534 with analog configuration data 2520. Configurable analog switches 2570-1 can include analog switches (one shown as SWx) that can be controlled by signals provided by digital bus (PhXfb, PhX). Configurable analog circuit block 2570-2 can include various analog circuit blocks, including one or more analog comparators 2520 and one or more programmable capacitances, IDACs or VDACs. One or more outputs (Vout) from comparators can be provided to digital bus system 2570-3. Programmable capacitances can be programmed by Cap Codes via digital bus system 2570-3.

Configurable digital blocks 2570-4 can include digital circuits configurable into various arithmetic logic functions by configuration data 2520. Such various arithmetic logic functions can include phase and/or feedback logic 2532, FFs 2536, and digital processing circuits 2516 as described herein. Configurable digital blocks 2570-4 can also include a capacitor controller 2574, which can store and provide capacitance codes to programmable capacitances in configurable analog circuit block 2570-2. Such a feature can enable reference capacitances (Cref), as described herein, that are configurable into any of various capacitance values.

Configuration data 2520 can configure device 2570 into a sensing device by coupling the various circuit components together according to any of the embodiments disclosed herein, or equivalents.

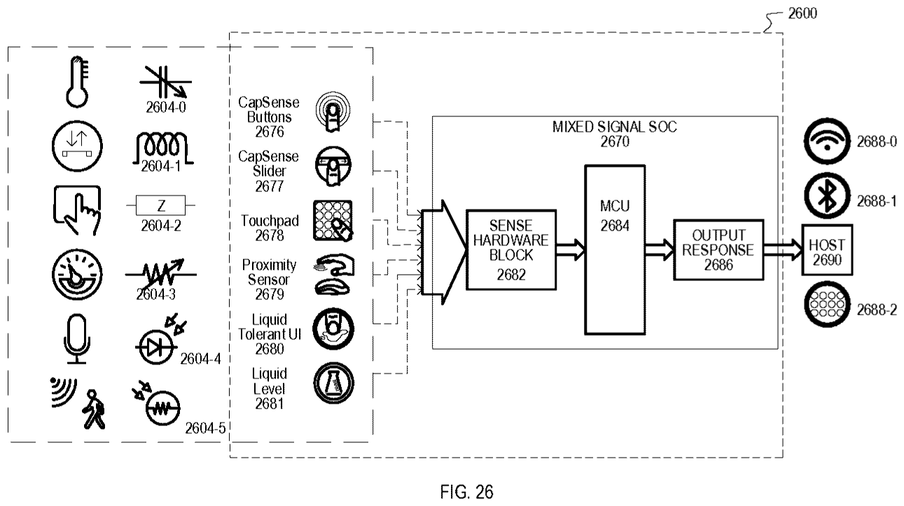

Embodiments can provide solutions to sensor needs in a wide variety of applications. FIG. 26 is a block diagram of sensing systems 2600 according to various embodiments. Sensing systems 2600 can include a mixed signal SoC 2670 having sense hardware blocks 2682, a microcontroller 2684, and can generate a digital sense output response 2686. Sense hardware blocks 2682 can include analog and digital circuits that form or can be configured into sensing circuits as described herein and equivalents. MCU 2684 can execute instructions for analyzing and/or processing sense values (e.g., raw code values) generated by hardware block 2682. Output response 2686 can be organized into a format suitable for an output destination.

Sensing systems 2600 can include any number of sensor input devices, including any of those described herein, as well as other including but not limited to: capacitance sense buttons 2676, capacitance sense sliders 2677, a touchpad 2678, a proximity sensor 2679, a liquid tolerant user interface 2680 or a liquid level detector 2681. Further, a system 2600 can accommodate any number of sensor mechanisms, including but not limited to: a variable capacitance 2604-0, a variable inductance 2604-1, a variable impedance 2604-2, a variable resistance 2604-3, a photocurrent generating device 2604-4 (e.g., PD or phototransistor), and/or a photoresistor 1604-5.

Sensing system 2600 can provide output results to any suitable destination location, including but not limited to: transmission according to a longer range wireless connection 2688-0, a short range wireless connection 2688-1, a user interface 2688-2 or directly to a host device 2690 via a wired connection.

While the various devices and systems have disclosed a number of sensing methods, additional methods will now be described with reference to flow diagrams.

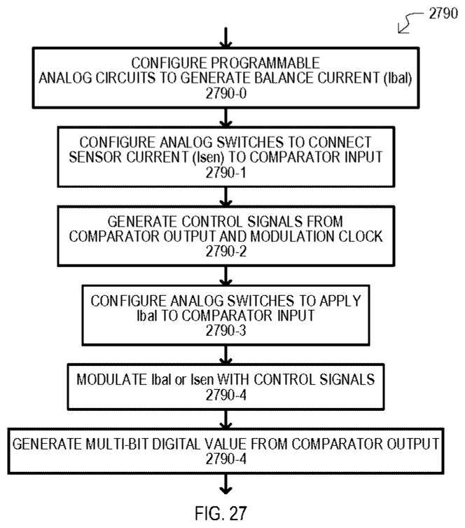

FIG. 27 is a flow diagram of a method 2790 according to an embodiment. A method 2790 can include configuring programmable analog circuits to generate a balance current (Ibal) 2790-0. Such an action can include configuring Ibal to have a magnitude and duration to balance an expected sensor current (Isen) at the input of a comparator 2790-0. Such an action can include any suitable steps, including but not limited to: providing configuration values for a programmable IDAC or configuring a switched capacitor circuit that generates Ibal. Analog switches can be configured to connect a sensor current to an input of a comparator 1790-1. Such an action can include controlling analog switches with switch control signals and/or configuration values to provide a conductive path from an external connection to a comparator circuit.

A method 2790 can further include generating control signals from an output of a comparator and a modulation clock 2790-2. In some embodiments, such an action can include using digital circuits to generate control signals synchronous with a modulation clock. Analog switches can be configured to apply Ibal to a comparator input 2790-3.

Such an action can include using configuration inputs to form a desired signal path for Ibal and/or dynamically enable a current path with switch control signals. In some embodiments, Ibal can be applied to a same comparator input as Isen, and flow in an opposite direction than Isen with respect to the comparator input. In other embodiments, Ibal can be applied to a different comparator input than Isen.

A method 2790 can also include modulating Ibal or Isen with the control signals 2790-4. Such an action can include enabling and disabling Ibal or Isen according to the control signals. In some embodiments, such an action can essentially serve as a feedback mechanism, forcing a voltage at comparator inputs in a direction opposite to its current state.

A multi-bit digital value can be generated from a comparator output 2790-4. Such an action can include any suitable conversion method, including those employed on back ends of sigma-delta modulators. In some embodiments, such an action can include sampling a comparator bit stream output.

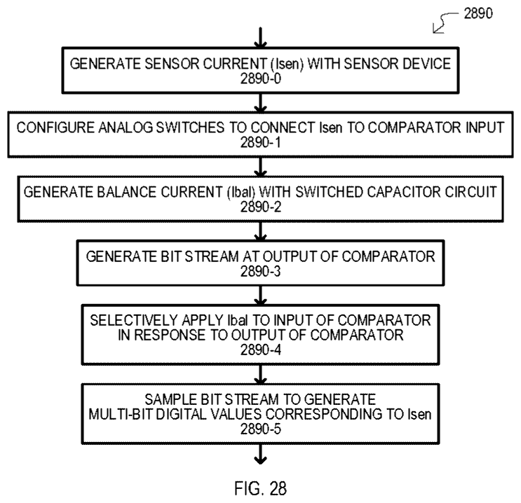

FIG. 28 is a flow diagram of a method 2890 according to another embodiment. A method 2890 can include generating Isen with a sensor device 2890-0. Such an action can include generating a sensor current according to any of the sensor mechanisms described herein, including but not limited to generating a current from: a photoelectric device, a variable capacitance, a variable resistance, a variable inductance, or a variable impedance. Analog switches can be configured to connect Isen to a comparator input 2890-1. Such an action can include configuring programmable switches to enable a static or dynamic path between a sensor and the comparator.

A method 2890 can include generating Ibal with a switched capacitor circuit 2890-1. Such an action can include any suitable switched capacitor circuit, including but not limited to charging a capacitor, then connecting a charged capacitor terminal to a low power supply to generate a negative Ibal source voltage and/or connecting a ground terminal of the capacitor to a high supply voltage to generate a higher than supply Ibal source voltage.

A method 2890 can also include generating a bit stream at the output of the comparator 2890-3. Such an action can include driving a comparator output between high and low states as Isen is received at inputs (and balanced with a Ibal). Ibal can be selectively applied to a comparator input in response to an output of the comparator 2890-4. Such an action can serve as a feedback mechanism, counteracting the effect of Isen at the comparator input.

A method 2890 can include sampling the bit stream to generate multi-bit digital values 2890-5. In some embodiments, such an action can include determining the amount of time a comparator output was high in a given sampling period.

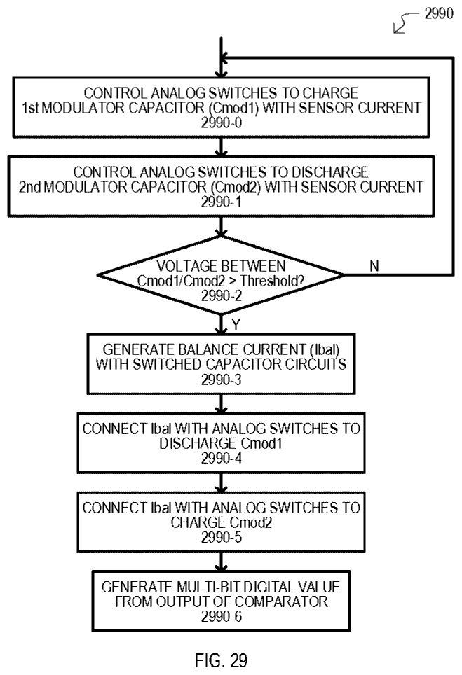

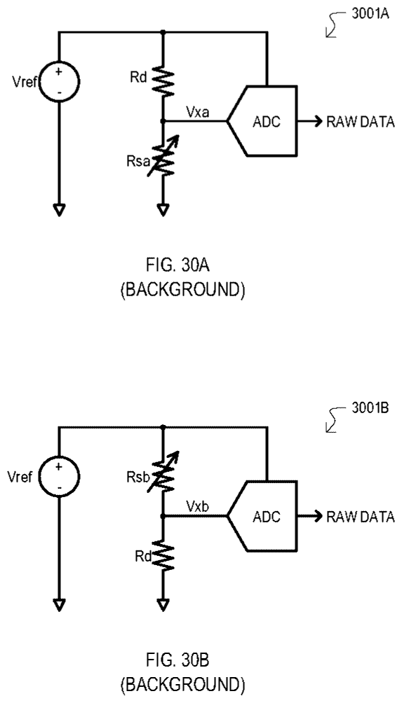

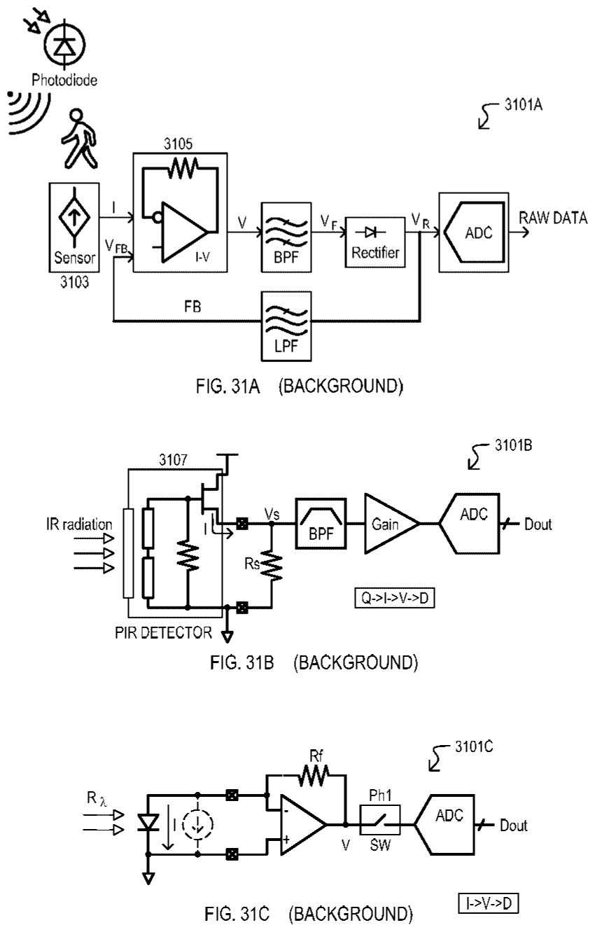

FIG. 29 is a flow diagram of another method 2990 according to a further embodiment. A method 2990 can include controlling analog switches to charge a first modulation capacitance (C mod 1) with a sensor current 2990-0. Analog switches can also be controlled to discharge a second modulation capacitance (C mod 2) with the sensor current 2990-1. Such an action can generate differential voltage between C mod 1 and a C mod 2.

A method 2990 can then determine if a voltage between Vc mod 1 and Vc mod 2 exceeds a threshold 2990-2. In some embodiments, such an action can include determining if a voltage difference between and C mod 1/C mod 2 exceeds the offset voltage of the comparator. However, alternate embodiments can include larger thresholds and/or hysteresis. If a threshold is not exceeded (N from 2990-2), a method 2990 can return to 2990-0 (generating a differential voltage between C mod 1 and C mod 2 with Isen).

If a threshold is exceeded (Y form 2990-2), a method 2990 can generate Ibal with switched capacitor circuits 2990-3. Such an action can include any of those described herein or equivalents. Ibal can be connected with analog switches to discharge C mod 1 2990-4. In addition, Ibal can be connected with analog switches to charge C mod 2 2990-5. Such an action can work against Isen, reducing a voltage difference between C mod 1 and C mod 2 created by Isen.

A multi-bit digital value can be generated from an output of the comparator 2990-6. Such an action can take the form of any of those described herein, or equivalents.

According to embodiments, a sensor system can include an analog-front-end compatible with various sensor type that is robust, high-performance, low-cost, low-power and low-area, relative to conventional approaches. Embodiments can enjoy use in any or all of resistive, capacitive, inductive and impedance sensing applications.

Resistance sensing applications can include, but are not limited to, temperature sensors, resistive force sensors, pressure sensors, photo-resistors, variable and adjusted resistor, resistive touchpad and button sensor. Unlike conventional systems, embodiments can be configured into a C-ADC, and not require a dedicated voltage ADC.

Embodiments can include photoelectric and/or pyroelectric sensing systems, including but not limited to: optical proximity detectors, motion detectors, and light-intensity sensing systems.

According to embodiments, a same architecture can be configured to operate with diverse sensor type, including microelectromechanical sensors, electret devices (e.g., microphones), piezoelectric sensors.

Advantageously, a same sensing architecture can be utilized for numerous different sensor types, or be deployed as a multi-sensor system (i.e., a system that uses multiple sensors of different types). This is in sharp contrast to conventional approaches which can have dedicated sensor circuits for each sensor type.

Advantageously, embodiments can modulate sensor and/or balance currents for a linear resistance-to-code response.

Embodiments can advantageously provide multi-sensing capabilities with a single integrated circuit (IC) device, including a mixed signal SoC formed with a same IC substrate. This is in contrast to conventional systems which can include a dedicated IC device for each sensor, which can be more costly, require greater area, and greater design complexity.

In some embodiments, sensor currents can be received directly by a C-ADC circuit. This is in contrast to conventional systems which can include an intermediate voltage generation step (e.g., active integrators, TIA, passive circuit elements). In this way, embodiments can be less costly, less complex, and easier to deploy than conventional systems.

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claims require more features than are expressly recited in each claim. Rather, inventive aspects lie in less than all features of a single foregoing disclosed embodiment. Thus, the claims following the detailed description are hereby expressly incorporated into this detailed description, with each claim standing on its own as a separate embodiment of this invention.

What is claimed is:

1-21. (canceled)

22. A capacitance to digital converter comprising:
an input for receiving signals from at least capacitance sensing electrode;
a sense switching section coupled to the input, the sense switching section for modulating the received signal on the input;
a comparator coupled to the sense switching section at a first comparator input and to a reference at a second comparator input;
a switch signal generator coupled to an output of the comparator;
a digital processing circuits coupled to an output of the switch signal generator; and
a balance current generator coupled to the first comparator input, the balance current generator for applying a balancing signal to the modulated receive signal,
wherein the digital processing circuits are for generating a digital signal representative of a current received on the first comparator input, and
wherein the switch signal generator provide control signals to the sense switching section and the balance current generator in response to an output signal from the comparator.

23. The capacitance to digital converter of claim 22, wherein the balance current generator comprises a configurable current source in series with a switch for receiving control signals from the switch signal generator.

24. The capacitance to digital converter of claim 23, wherein the configurable current source and switch are coupled between the first comparator input and a supply voltage.

25. The capacitance to digital converter of claim 23, wherein the configurable current source and switch are coupled between the first comparator input and ground.

26. The capacitance to digital converter of claim 22, the sense switching section comprises at least one switch for modulating a current received at the input in response to at least one control signal from the switch signal generator.

27. The capacitance to digital converter of claim 22, wherein the output of the comparator is latched in synchronism with a modulation clock to generate a bit stream output.

28. The capacitance to digital converter of claim 22, further comprising a modulation capacitance coupled to the sense switching section, the modulation capacitance for modulating the received signal on the input.

29. A device comprising:
at least on capacitance sensing electrode; and
a capacitance to digital conversion circuit comprising:
an input for receiving signals from at least capacitance sensing electrode;
a sense switching section coupled to the input, the sense switching section for modulating the received signal on the input;
a comparator coupled to the sense switching section at a first comparator input and to a reference at a second comparator input;
a switch signal generator coupled to an output of the comparator;
a digital processing circuits coupled to an output of the switch signal generator; and
a balance current generator coupled to the first comparator input, the balance current generator for applying a balancing signal to the modulated receive signal;
wherein the digital processing circuits are for generating a digital signal representative of a current received on the first comparator input, and
wherein the switch signal generator provide control signals to the sense switching section and the balance current generator in response to an output signal from the comparator.

30. The capacitance to digital converter of claim 29, wherein the balance current generator comprises a configurable current source in series with a switch for receiving control signals from the switch signal generator.

31. The capacitance to digital converter of claim 30, wherein the configurable current source and switch are coupled between the first comparator input and a supply voltage.

32. The capacitance to digital converter of claim 30, wherein the configurable current source and switch are coupled between the first comparator input and ground.

33. The capacitance to digital converter of claim 29, the sense switching section comprises at least one switch for modulating a current received at the input in response to at least one control signal from the switch signal generator.

34. The capacitance to digital converter of claim 22, wherein the output of the comparator is latched in synchronism with a modulation clock to generate a bit stream output.

35. The capacitance to digital converter of claim 22, further comprising a modulation capacitance coupled to the sense switching section, the modulation capacitance for modulating the received signal on the input.

36. A method comprising:
receiving, at an input, a current signal from at capacitance sensing electrode
converting the received current signal to a voltage, the voltage received at input of a comparator;
applying a balancing current to the received current signal, the balancing circuit in response to control signals from a balance current generator coupled to an output of the comparator,
comparing the received current signal to a reference signal;
generating a bit stream in response to the comparison; and
generating a digital value representative of the bit stream.

37. The method of claim of claim 36, wherein the balancing current is applied as a current to ground.

38. The method of claim of claim 36, wherein the balancing current is applied as a current to a supply voltage.

39. The method of claim 36, wherein generating the bitstream comprises modulating the combined received current signal and balancing current in response to the output of the comparator.

40. The method of claim 39, wherein modulating the combined received current signal and balancing current comprises charging and discharging a modulation capacitance in response to control signals derived from the output of the comparator.

41. The method of claim 39, wherein the output of the comparator is latched in synchronism with a modulation clock to generate the bit stream.
